(19) United States
(12) Patent Application Publication
(10) Pub. No.: US 2019/0161850 A1
(43) Pub. Date: May 30, 2019

(54) ULTRA-FINE GRAIN SIZE TANTALUM SPUTTERING TARGETS WITH IMPROVED VOLTAGE PERFORMANCE AND METHODS THEREBY

(71) Applicant: Tosoh SMD, Inc., Grove City, OH (US)

(72) Inventors: Alex Kuhn, Columbus, OH (US); Eugene Ivanov, Grove City, OH (US)

(21) Appl. No.: 16/160,301

(22) Filed: Oct. 15, 2018

Related U.S. Application Data
(60) Provisional application No. 62/592,597, filed on Nov. 30, 2017.

(51) Int. Cl. C23C 14/34

(52) U.S. Cl. CPC C23C 14/3414; C22F 1/16

(57) ABSTRACT

A method of making a tantalum sputtering target providing the steps of: a) providing a tantalum ingot; b) forging and annealing the tantalum ingot to provide a grain refined tantalum billet; and c) processing the grain refined tantalum billet to produce a tantalum sputtering target with a reduced grain size and a reduced grain size standard deviation. A tantalum sputtering targeting having a purity of at least 99.9%, a grain size of about 30 μm or less, and a grain size standard deviation of about 20 μm or less. A sputtering target manufactured in accordance with this invention will have a more consistent and stable voltage performance throughout target life, compared to prior methods with a larger grain size and grain size deviation. A more consistent and stable voltage performance leads to improved film uniformity.

### CROSS-REFERENCE TO RELATED APPLICATION

This application claims the priority of U.S. Provisional Patent Application Ser. No. 62/592,597 filed Nov. 30, 2017 and is incorporated herein by reference.

### FIELD OF INVENTION

The present invention relates to a tantalum (Ta) sputtering target with an ultra-fine grain size and low grain size standard deviation. A sputtering target manufactured in accordance to this invention has a more consistent and stable voltage performance throughout target life, as compared to prior methods with a larger grain size and grain size standard deviation. Thus, this invention provides a Ta sputtering target that yields an improved film uniformity.

### BACKGROUND

In magnetron sputtering, DC power is applied to the target during a film deposition cycle. The power applied to the target is kept constant, and as a result, the target voltage and current vary to maintain a constant power. A consistent target voltage change through target life is desirable in order to achieve the best thin film properties.

Variations in voltage can lead to variations in deposition rate, which can negatively impact film uniformity and resistivity. Voltage variation can also require the user to continuously modify sputtering parameters through target life, which is not desired. Current embodiments of tantalum sputtering targets have variable target voltage through target life, which results in less than ideal thin film properties through target life, and more user intervention than desired. The voltage variation seen in prior methods is due to a larger grain size and grain size standard deviation.

Therefore, what is needed is a sputtering target that has an ultra-fine grain size and low grain size standard deviation, which leads to a consistent and stable voltage through target life, leading to superior sputter performance and thin film properties.

### SUMMARY OF INVENTION

In one exemplary embodiment, a method of making a tantalum sputtering target is disclosed. The method of making a tantalum sputtering target comprises the steps of: a) providing a tantalum ingot; b) forging and annealing the tantalum ingot to provide a grain refined tantalum billet; and c) processing the grain refined tantalum billet to produce a tantalum sputtering target with a reduced grain size and a reduced grain size standard deviation. In some embodiments, the tantalum ingot is either an E-beam melted tantalum ingot or a vacuum arc-melted tantalum ingot. In some embodiments, the processing of the grain refined tantalum billet is achieved by cryogenic rolling, asymmetric rolling, severe plastic deformation, equal channel angular extrusion (ECAE), friction stir processing, or micro-alloying.

In other embodiments, the processing of said grain refined tantalum billet is achieved by a combination of micro-alloying and either cryogenic rolling, asymmetric rolling, severe plastic deformation, equal channel angular extrusion (ECAE), or friction stir processing. In such embodiments, the step of micro-alloying includes addition of a grain refining element or elements to the tantalum. Good candidates for micro-alloying include elements that are insoluble with the host.

In yet another exemplary embodiment, the tantalum sputtering target of the present invention comprises a voltage variation (root-mean-square-deviation-RMSD) through target life of about 3.0 volts or less. In some embodiments, the tantalum sputtering target of the present invention has a grain size of 30 μm or less and a grain size standard deviation of 20 μm or less. In some embodiments, the tantalum sputtering target of the present invention has a purity of at least 99.9% and a grain size of about 30 μm or less. In other embodiments, the tantalum sputtering target of the present invention has a purity of at least 99.9% and a grain size standard deviation of about 20 μm or less. In other embodiments, the tantalum sputtering target of the present invention has a purity of at least 99.9%, a grain size of about 30 μm or less, and a grain size standard deviation of about 20 μm or less.

In yet another embodiment of the present invention, a thin film for semiconductor applications is created by using the tantalum sputtering target according to the present methods. In such embodiments, the thin film has a film thickness uniformity through target life of about 1.5% or less, and a variation in film resistivity of about 3.00% or less. In other embodiments, a thin film for semiconductor applications is created by using a tantalum sputtering target with a purity of at least 99.9%, a grain size of about 30 μm or less, and a grain size standard deviation of about 20 μm or less.

In yet another embodiment of the present invention, a method of making a tantalum sputtering target is provided. The method comprises the steps of: a) providing a tantalum ingot; b) forging and annealing the tantalum ingot to provide a grain refined tantalum billet; and c) processing the grain refined tantalum billet to produce a tantalum sputtering target with a purity of at least 99.9%, a grain size of about 30 μm or less, and a grain size standard deviation of about 20 μm or less. In such embodiments, the tantalum ingot is either an E-beam melted tantalum ingot or a vacuum arc-melted tantalum ingot. In such embodiments, the processing of the grain refined tantalum billet is achieved by cryogenic rolling, asymmetric rolling, severe plastic deformation, equal channel angular extrusion (ECAE), friction stir processing, or micro-alloying. In other embodiments, the processing of the grain refined tantalum billet is achieved by a combination of micro-alloying and either cryogenic rolling, asymmetric rolling, severe plastic deformation, equal channel angular extrusion (ECAE), or friction stir processing. In such embodiments, the tantalum sputtering target comprises a voltage variation (RMSD) through target life of about 3.0 volts or less.

In yet another embodiment of the present invention, a tantalum sputtering target is provided. In some embodiments, the tantalum sputtering target comprises a purity of at least 99.9%; a grain-size of less than 30 μm; a grain-size standard deviation of less than 20 μm; and a voltage variation through target life of about 3.0 volts or less. In some embodiments, the grain-size is less than 25 μm. In some embodiments, the grain-size standard deviation is less than 15 μm. In some embodiments, the voltage variation through target life is about 2.0 volts or less. In some embodiments, the tantalum sputtering target provides for a thin film for semiconductor applications, wherein variation in film thickness uniformity through target life is about 1.5% or less, and a variation in film resistivity of about 3.00% or less. In some embodiments, the tantalum sputtering target further comprises a grain refining element or elements. In some embodiments, the grain refining element or elements comprise a member selected from the group consisting of Sc, Y, Si, rare earth metals, and mixtures thereof. In some embodiments, the grain refining element is Y, present in an amount of about 1-40 ppm based upon 1 million parts of Ta.

### BRIEF DESCRIPTION OF THE DRAWINGS

FIG. 1 is a graph depicting the voltage vs. target life for a tantalum sputtering target; manufactured in accordance with this invention;

FIG. 2 is a graph depicting the voltage vs. target life for a tantalum sputtering target manufactured using prior methods; and

FIG. 3 is a graph depicting the voltage vs. target life for a tantalum sputtering target manufactured using prior methods.

### DESCRIPTION OF THE INVENTION

The present invention generally describes a tantalum (Ta) sputtering target with an ultra-fine grain size and low grain size standard deviation and methods thereby. A sputtering target manufactured in accordance with the present invention has a more consistent and stable voltage performance throughout the target life and yields an improved film uniformity.

The present invention provides a method of making a tantalum sputtering target. In one exemplary embodiment, the method comprises: a) providing a tantalum ingot; b) forging and annealing the tantalum ingot to provide a grain refined tantalum billet; and c) processing the grain refined tantalum billet to produce a tantalum sputtering target with a reduced grain size and a reduced grain size standard deviation.

The method of the present invention provides a fine grain size sputtering target that can be achieved using a variety of methods and has the ability to develop an ultra-fine grain size compared to conventional methods. For example, sputtering targets produced by conventional methods yield a target with variable voltage performance throughout target life. Such sputtering targets obtained through conventional methods have a grain size on average between 45 μm and 100 μm and a recrystallization rate of 99% or higher, which is not ideal.

In one embodiment, the method of the present invention first provides a tantalum ingot. In some embodiments, the tantalum ingot is either an E-beam melted tantalum ingot or a vacuum arc-melted tantalum ingot. In some embodiments, the E-beam melted tantalum ingot is essentially pure and does not include any significant elemental additions. In some embodiments, the method of the present invention further provides the step of forging and annealing the tantalum ingot to provide a grain refined tantalum billet.

In some embodiments, the method of the present invention provides further processing the grain refined tantalum billet to produce a tantalum sputtering target with a reduced grain size and a reduced grain size standard deviation. In some embodiments, processing of the grain refined tantalum billet can be achieved by cryogenic rolling, asymmetric rolling, severe plastic deformation, equal channel angular extrusion (ECAE), friction stir processing, or micro-alloying.

In some embodiments, the present invention provides a tantalum sputtering target obtained by cryogenic rolling. Cryogenic rolling of the present invention is performed at a temperatures −190° C. or lower. In some embodiments, subsequent to the cryogenic rolling, the sputtering target blank is subjected to a recrystallization anneal.

In some embodiments, the tantalum sputtering target obtained by cryogenic rolling has an ultra-fine grain size of less than 30 μm and low grain size standard deviation of less than 20 μm. In other embodiments, the tantalum sputtering target obtained by cryogenic rolling has an ultra-fine grain size of less than 25 μm and low grain size standard deviation of less than 15 μm.

In other embodiments, the present invention provides a tantalum sputtering target obtained by asymmetric rolling. One skilled in the art would understand that asymmetric rolling is a process where the conditions of the top roll are different compared to the conditions of the bottom roll. The asymmetric rolling condition imparts significantly more shear strain into the part compared to conventional rolling methods. This increased shear strain promotes increased dislocation development which leads to a finer microstructure after the recrystallization anneal. In some embodiments, the asymmetric roll condition can be achieved by rolling speed differential, roll diameter differential, or roller friction differential.

In some embodiments, the tantalum sputtering target obtained by asymmetric rolling has an ultra-fine grain size of less than 30 μm and low grain size standard deviation of less than 20 μm. In other embodiments, the tantalum sputtering target obtained by asymmetric rolling has an ultra-fine grain size of less than 25 μm and low grain size standard deviation of less than 15 μm.

In other embodiments, the present invention provides a tantalum sputtering target obtained by severe plastic deformation. During deformation, dislocations form within the existing grain structure. As the deformation increases, the dislocations align within the grain in a lower energy configuration known as a low angle grain boundary. As the deformation continues, the density of dislocations increases which in turn decrease the spacing between dislocations along the low angle grain boundary.

Eventually the cores of the dislocations overlap forming a distinct high angle grain boundary, essentially splitting the original grain in two. In some embodiments, by significantly deforming the material 85% thickness reduction or greater and foregoing the recrystallization anneal, the ultra-fine grain structure developed during deformation is preserved.

In some embodiments, the tantalum sputtering target obtained by severe plastic deformation has an ultra-fine grain size of less than 30 μm and low grain size standard deviation of less than 20 μm. In other embodiments, the tantalum sputtering target obtained by severe plastic deformation has an ultra-fine grain size of less than 25 μm and low grain size standard deviation of less than 15 μm.

In other embodiments, the present invention provides a tantalum sputtering target obtained by equal channel angular extrusion (ECAE). One skilled in the art would understand that ECAE is a deformation method that imparts significant cold work to the work piece without a reduction in cross-sectional area, which is accomplished by forcing the work piece through a channel with angles. Subsequently, as the metal flows around the angle corner, very high strain is imparted onto the work piece.

In some embodiments, this high strain promotes increased dislocation development which leads to a finer microstructure after the recrystallization anneal. In some embodiments, the tantalum sputtering target obtained by ECAE has an ultra-fine grain size of less than 30 μm and low grain size standard deviation of less than 20 μm. In other embodiments, the tantalum sputtering target obtained by ECAE has an ultra-fine grain size of less than 25 μm and low grain size standard deviation of less than 15 μm.

In other embodiments, the present invention provides a tantalum sputtering target obtained by friction stir processing. In some embodiments, friction stir processing is a method to refine existing grain structure. Friction is generated between a rotating tool immersed into the work piece. This leads to a softened region which allows the tool to traverse throughout the material where the rotating tool breaks up and refines the existing grains. In some embodiments, the rotating tool is traversed throughout the whole sputtering target to refine the material.

In some embodiments, the tantalum sputtering target obtained by friction stir processing has an ultra-fine grain size of less than 30 μm and low grain size standard deviation of less than 20 μm. In other embodiments, the tantalum sputtering target obtained by friction stir processing has an ultra-fine grain size of less than 25 μm and low grain size standard deviation of less than 15 μm.

In other embodiments, the present invention provides a tantalum sputtering target obtained by micro-alloying tantalum with a grain refining element or elements to provide a micro-alloyed tantalum ingot. In some embodiments, an ultra-fine grain structure can be achieved by micro-alloying the tantalum with a plurality of grain refining elements and a combination of one of aforementioned methods. A good candidate for micro-alloying is an element that is insoluble with the host. This results in the development of precipitates that pin grain boundaries and retard grain growth.

With regard to the grain refining elements that may be added to the Ta, rare earth elements, Sc, Y, Si, may be mentioned. Typically, the grain refining element(s) are added to the Ta in an amount of about 1-40 ppm based upon 1 million parts of Ta. In some exemplary embodiments, the grain refining elements may be added in an amount of about 10-25 ppm.

In some embodiments, a tantalum sputtering target is achieved by a combination of micro-alloying and either cryogenic rolling, asymmetric rolling, severe plastic deformation, equal channel angular extrusion (ECAE), or friction stir processing. In such embodiments, the tantalum sputtering target has an ultra-fine grain size of less than 30 μm and low grain size standard deviation of less than 20 μm, and in other such embodiments, the tantalum sputtering target has an ultra-fine grain size of less than 25 μm and low grain size standard deviation of less than 15 μm.

Voltage variation through target life is quantified using the root-mean-square-deviation (RMSD). The RMSD is a measure of how much observed voltage values vary from predicted values. The RMSD is the standard deviation of the differences between predicted values from the linear regression and observed values. A low RMSD deviation indicates that the observed values are close to the predicted values, and that voltage variation through target life is low. The tantalum sputtering target of the present invention comprises a voltage variation (RMSD) through target life of about 3.0 volts or less. In other embodiments, the voltage variation (RMSD) through target life is about 1.9 volts or less. To compare voltage variation between targets, the root-mean-square-deviation (RMSD) of voltage through target life is quantified. In some embodiments, a tantalum sputtering target with exemplary voltage performance comprises a low RMSD. In such embodiments, the tantalum sputtering target comprises an ultra-fine grain size less than 30 μm and low grain size standard deviation less than 20 μm. Such embodiments provide a tantalum sputtering target with consistent and exemplary voltage performance through target life.

In some embodiments, the tantalum sputtering target has a grain size of 30 μm or less and a grain size standard deviation of 20 μm or less. In some embodiments, the tantalum sputtering target has a purity of at least 99.9% and a grain size of about 30 μm or less. In some embodiments, the tantalum sputtering target has a purity of at least 99.9% and a grain size standard deviation of about 20 μm or less. In other embodiments, the tantalum sputtering target has a purity of at least 99.9%, a grain size of about 30 μm or less, and a grain size standard deviation of about 20 μm or less.

The present invention further provides for a thin film for semiconductor applications is obtained by using the tantalum sputtering target obtained by the aforementioned methods. In some embodiments, the film thickness uniformity ((Std. Dev)/Mean)*100% through target life is about 1.5% or less, and a variation in film resistivity ((Max−min)/(Max+min))*100% of about 3.00% or less.

In some embodiments, the thin film for semiconductor applications is obtained from a tantalum sputtering target having a purity of at least 99.9%, a grain size of about 30 μm or less, and a grain size standard deviation of about 20 μm or less.

In the foregoing specification, the invention has been described with reference to specific embodiments thereof. It will be evident that various modifications and changes can be made to the methods and targets of the invention without departing from the broader spirit or scope of the invention as set forth in the appended claims. Accordingly, the specification is to be regarded in an illustrative rather than a restrictive sense.

### EXAMPLES

The following non-limiting examples are provided to further illustrate the present invention. All grain size and grain size standard deviation measurements referred to herein were obtained using electron backscattered diffraction (EBSD).

### Example 1

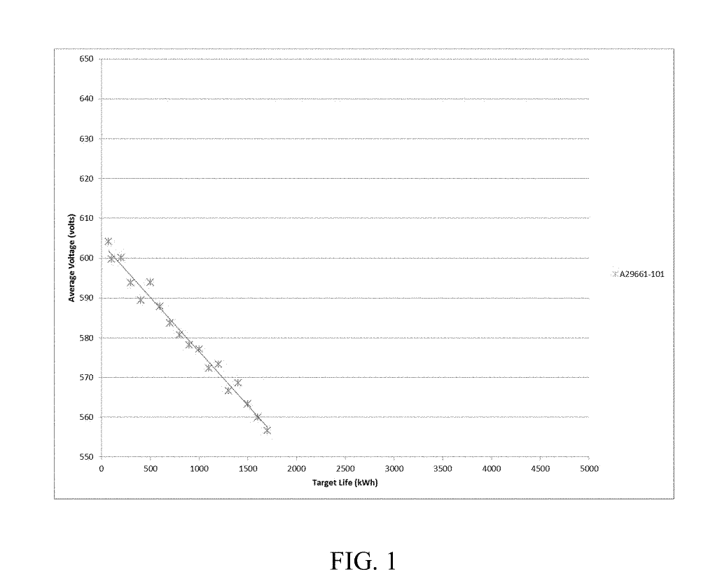

As shown in FIG. 1, a tantalum target A29661-101 manufactured according to this invention yielded a sputtering target blank 18.50″ Dia×0.330″ thick. The tantalum target A29661-101 had a grain size of 21.6 μm, and a grain size standard deviation of 13.5 μm.

The tantalum target A29661-101 was sputtered for 1700 kWh's, and exhibited superior voltage performance with a RMSD of 1.870 volts. The benefits of superior voltage performance is reflected in improved film uniformity ((Std. Dev)/Mean)*100%, with an average through target life of 1.44%. Variation in film resistivity ((Max−min)/(Max+min))*100% is also improved, with an average through target life of 2.80%.

### Comparative Example 1

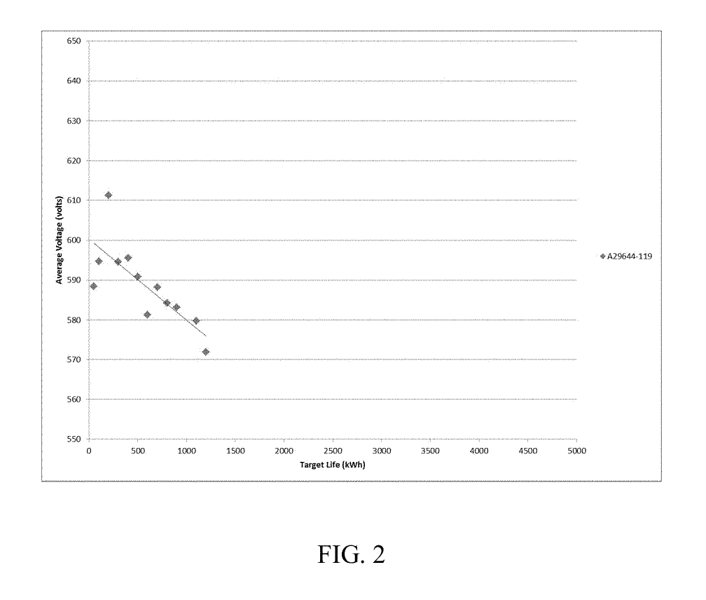

As shown in FIG. 2, a tantalum target A29644-119 was manufactured using conventional methods, starting from an E-beam ingot. The E-beam ingot underwent a series of forging and annealing steps to achieve a grain refined billet with an average grain size <250 μm. A section from this billet was sawed and it was forged and cold rolled into a plate that was 18.50″ Dia×0.330″ thick. The resulting plate underwent a recrystallization anneal at 1000 C to obtain a target with a grain size of 49.0 μm and a grain size standard deviation 29.4 μm.

The tantalum target A29644-119 was sputtered for 1200 kWh's, and exhibited poor voltage performance with a RMSD of 6.054 volts. The increased voltage variation led to worse film uniformity ((Std. Dev)/Mean)*100% compared to target A29661-101 (manufactured according to this invention), with an average through target life of 1.74%. Variation in film resistivity ((Max−min)/(Max+min))*100% was also worse compared to target A29661-101, with an average through target life of 3.25%.

### Comparative Example 2

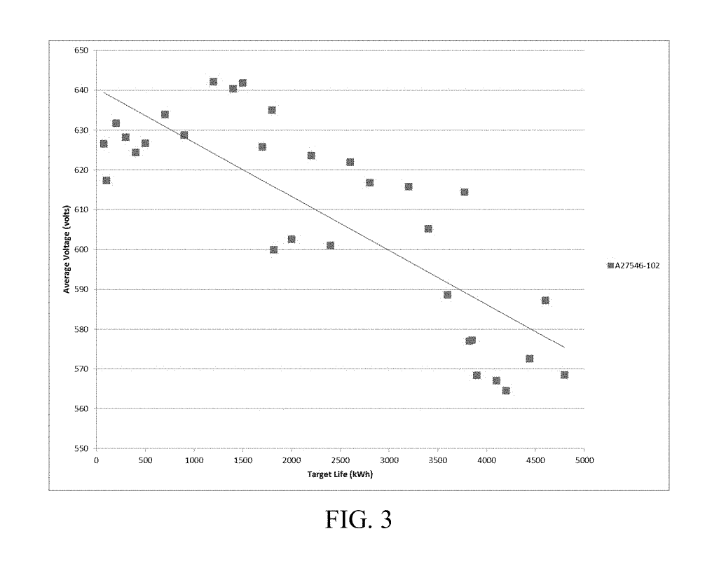

As shown in FIG. 3, a tantalum target A27546-102 was manufactured using conventional methods, starting from an E-beam ingot. The E-beam ingot underwent a series of forging and annealing steps to achieve a grain refined billet with an average grain size <250 μm. A section from this billet was sawed and it was forged and cold rolled into a plate that was 18.50″ Dia×0.580″ thick. The resulting plate underwent a recrystallization anneal at 1000 C to obtain a target with a grain size of 122.4 μm and a grain size standard deviation 90.4 μm.

The tantalum target A27546-102 was sputtered for 4800 kWh's, and exhibited poor voltage performance with a RMSD of 14.100 volts. The increased voltage variation led to worse film uniformity ((Std. Dev)/Mean)*100% compared to target A29661-101 (manufactured according to this invention), with an average through target life of 1.95%. Variation in film resistivity ((Max−min)/(Max+min))*100% was also worse compared to target A29661-101, with an average through target life of 3.30%. All grain size and grain size standard deviation measurements made herein were calculated using electron backscattered diffraction (EBSD).

A summary of results can be seen in Table 1 below.

TABLE 1

| | | | Grain Size | Voltage | Film Uniformity | Variation in Film |
|---|---|---|---|---|---|---|
| | | | Std. | Fit, | ((Std. Dev.)/ | Resistivity ((Max − min)/ |
| Target ID | Method | Grain Size | Dev. | RMSD | Mean)*100% | (Max + min))*100% |
| A29661-101 | New | 21.6 | 13.5 | 1.9 | 1.44% | 2.80% |
| A29644-119 | Prior | 49.0 | 29.4 | 6.1 | 1.74% | 3.25% |
| A27546-102 | Prior | 122.4 | 90.4 | 14.1 | 1.95% | 3.30% |

From the above, it is apparent that a target made in accordance with the invention undergoes some of the same starting process steps as are used in conventional target manufacture.

Starting with either an E-beam melted tantalum ingot or vacuum arc re-melted ingot, said E-beam ingot is pure greater than 99.99%. The ingot undergoes a series of forging and anneal steps, to achieve a grain refined tantalum billet. At this point, the instant manufacturing process diverges from conventional methods. The tantalum sputtering target is manufactured using cryogenic rolling, asymmetric rolling, severe plastic deformation, equal channel angular extrusion (ECAE), friction stir processing, or micro-alloying, to achieve an ultra-fine grain size. The subsequent target has a purity 99.99% or greater and a grain size 30 μm or less, grain size standard deviation 20 μm or less. A target manufactured using one of the above methods and the resulting reduced grain size and grain size standard deviation allow it to have superior voltage performance and reduced voltage variation through target life.

1. A method of making a tantalum sputtering target comprising:
a) providing tantalum;
b) forming a tantalum ingot from said tantalum; and
c) forging and annealing said tantalum ingot to provide a tantalum billet, and
d) processing said tantalum billet to provide a grain refined tantalum billet useful to form a tantalum sputtering target having a reduced grain size of ≤30 μm and a reduced grain size standard deviation of ≤20 μm.

2. The method as in claim 1, wherein said tantalum ingot is either an E-beam melted tantalum ingot or a vacuum arc-melted tantalum ingot.

3. The method as in claim 1, wherein said processing d) of said tantalum billet is achieved by cryogenic rolling, asymmetric rolling, severe plastic deformation, equal channel angular extrusion (ECAE), friction stir processing, or micro-alloying.

4. The method as in claim 1, wherein said processing d) is achieved by micro-alloying, said micro-alloying comprising adding a grain refining element or elements to said tantalum.

5. The method as in claim 1, wherein said grain refining element or elements comprise a member selected from the group consisting of Sc, Y, Si, and rare earth metals, and mixtures thereof.

6. The method as recited in claim 5, wherein said grain refining element is Y.

7. The method as in claim 4, wherein said processing d) also includes either cryogenic rolling, asymmetric rolling, severe plastic deformation, equal channel angular extrusion (ECAE) or friction stir processing.

8. The method as in claim 1, wherein said tantalum sputtering target comprises a voltage variation (RMSD) through target life of about 3.0 volts or less.

9. The method as in claim 8, wherein said tantalum sputtering target comprises a voltage variation (RMSD) through target life of about 1.9 volts or less.

10. The method as in claim 1, wherein said tantalum sputtering target has a purity of at least 99.9%.

11. A thin film for semiconductor applications created by using the tantalum sputtering target according to claim 1, where variation in film thickness uniformity through target life is about 1.5% or less, and a variation in film resistivity of about 3.00% or less.

12. The thin film as in claim 11, wherein said tantalum sputtering target has a purity of at least 99.9%, a grain size of about 30 μm or less, and a grain size standard deviation of about 20 μm or less.

13. A tantalum sputtering target comprising:
a purity of at least 99.9%;
a grain-size of less than 30 μm;
a grain-size standard deviation of less than 20 μm; and
a voltage variation through target life of about 3.0 volts or less.

14. The tantalum sputtering target of claim 13, wherein said grain-size is less than 25 μm.

15. The tantalum sputtering target of claim 13, wherein said grain-size standard deviation is less than 15 μm.

16. The tantalum sputtering target of claim 13, wherein said voltage variation through target life is about 2.0 volts or less.

17. The tantalum sputtering target of claim 13, wherein said tantalum sputtering target provides for a thin film for semiconductor applications, wherein variation in film thickness uniformity through target life is about 1.5% or less, and a variation in film resistivity of about 3.00% or less.

18. The tantalum sputtering target of claim 13, further comprising a grain refining element or elements.

19. The tantalum sputtering target of claim 18, wherein said grain refining element or elements comprise a member selected from the group consisting of Sc, Y, Si, rare earth metals, and mixtures thereof.

20. The tantalum sputtering target of claim 19, wherein said grain refining element is Y, present in an amount of about 1-40 ppm based upon 1 million parts of Ta.
